(19) United States
(12) Patent Application Publication
(10) Pub. No.: US 2026/0255613 A1
(43) Pub. Date: Aug. 27, 2026

(54) SEMICONDUCTOR DEVICE AND METHOD OF MANUFACTURING SEMICONDUCTOR DEVICE

(71) Applicant: SK hynix Inc., Icheon-si (KR)

(72) Inventors: Myoungsub KIM, Icheon-si (KR); Won Jun LEE, Icheon-si (KR); So Young YIM, Icheon-si (KR)

(21) Appl. No.: 19/319,300

(22) Filed: Sep. 4, 2025

(30) Foreign Application Priority Data
Feb. 21, 2025 (KR) 10-2025-0022953

(51) Int. Cl. H10B 63/00

(52) U.S. Cl. CPC H10B 63/84; H10B 63/24

(57) ABSTRACT

A semiconductor device includes: row lines extending along a first direction; column lines extending along a second direction that intersects the first direction; memory cells located between the row lines and the column lines and including variable resistance layers; and a first gap-fill insulating layer including a first portion located between an adjacent pair of the row lines in the second direction and a second portion located between an adjacent pair of the memory cells in the second direction. The first portion has a first nitrogen concentration, and the second portion has a second nitrogen concentration higher than the first nitrogen concentration.

### CROSS-REFERENCE TO RELATED APPLICATION

This application claims priority under 35 U.S.C. § 119 to Korean Patent Application No. 10-2025-0022953 filed on Feb. 21, 2025, which is incorporated herein by reference in its entirety.

### BACKGROUND

### 1. Technical Field

Embodiments of the present disclosure relate to an electronic device, and more particularly, to a semiconductor device and a method of manufacturing the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device may include: row lines extending along a first direction; column lines extending along a second direction that intersects the first direction; memory cells located between the row lines and the column lines and including variable resistance layers; and a first gap-fill insulating layer including a first portion located between an adjacent pair of the row lines in the second direction and a second portion located between an adjacent pair of the memory cells in the second direction, the first portion having a first nitrogen concentration, and the second portion having a second nitrogen concentration higher than the first nitrogen concentration.

In an embodiment, a semiconductor device may include: a row line extending along a first direction; a column line extending along a second direction that intersects the first direction; a memory cell located between the row line and the column line and including a variable resistance layer; and a gap-fill insulating layer covering a sidewall of the memory cell, and having a nitrogen concentration gradient, the nitrogen concentration gradient increasing from a top of the gap-fill insulating layer to a first level corresponding to the variable resistance layer and decreasing from the first level to a bottom of the gap-fill insulating layer.

In an embodiment, a method of manufacturing a semiconductor device may include: forming cell lines that extend along a first direction and include variable resistance layers; forming a first flowable oxide layer on the cell lines; heat-treating the first flowable oxide layer; forming a first gap-fill insulating layer between the cell lines by planarizing the heat-treated first flowable oxide layer; and performing first nitrogen plasma treatment on the first gap-fill insulating layer.

In an embodiment, a method of manufacturing a semiconductor device may include: forming cell lines that extend along a first direction and include variable resistance layers; forming a first gap-fill insulating layer between the cell lines; forming memory cells by etching the cell lines and the first gap-fill insulating layer, the memory cells being arranged in the first direction and a second direction intersecting the first direction; forming a flowable oxide layer on the memory cells; heat-treating the flowable oxide layer; forming a second gap-fill insulating layer between the memory cells by planarizing the heat-treated flowable oxide layer; and performing nitrogen plasma treatment on the second gap-fill insulating layer.

### BRIEF DESCRIPTION OF THE DRAWINGS

FIGS. 1A, 1B, and 1C are diagrams illustrating the structure of a semiconductor device in accordance with an embodiment.

FIGS. 2A and 2B are diagrams illustrating characteristics of a semiconductor device in accordance with an embodiment.

FIGS. 3A, 4A, 5A, and 6A, FIGS. 3B, 4B, 5B, and 6B, and FIGS. 3C, 4C, 5C, and 6C are diagrams for describing a method of manufacturing a semiconductor device in accordance with an embodiment.

FIGS. 7A and 7B are diagrams for describing a method of manufacturing a semiconductor device in accordance with an embodiment.

### DETAILED DESCRIPTION

Various embodiments are directed to a semiconductor device having a stable structure and improved characteristics and a method of manufacturing the semiconductor device.

By stacking memory cells in three dimensions, it is possible to improve the degree of integration of a semiconductor device. It is also possible to provide a semiconductor device having a stable structure and improved reliability. As used herein, including in the claims, the term ‘or’ in a list of items (e.g., a list introduced by phrases such as ‘at least one of,’ ‘one or more of,’ or ‘one or both of’) is intended to be inclusive unless explicitly stated otherwise. Specifically, the term ‘or’ should be interpreted to cover any individual item in the list, any combination of items in the list, or all items in the list. For example, a phrase such as ‘at least one of A, B, or C’ is intended to encompass A alone, B alone, C alone, any combination of A and B, A and C, or B and C, as well as A, B, and C together. This inclusive interpretation applies unless an explicit indication to the contrary is provided in a particular context. Moreover, a first element “on” a second element indicates that the first element can be “directly on” the second element, or that at least one intervening element can be interposed between the first and second elements.

Hereafter, embodiments in accordance with the technical spirit of the present disclosure will be described with reference to the accompanying drawings.

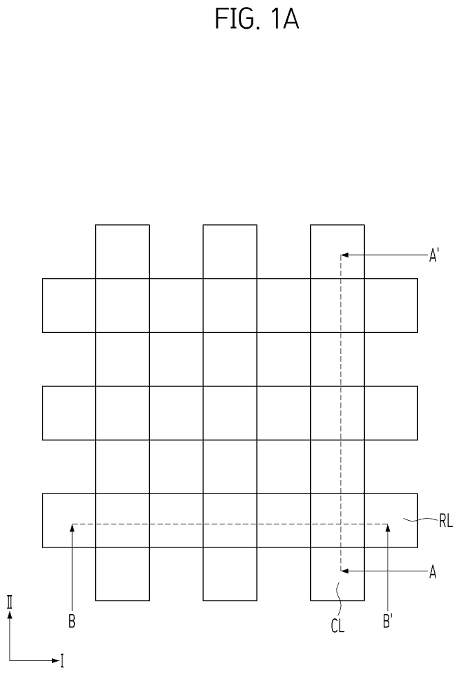

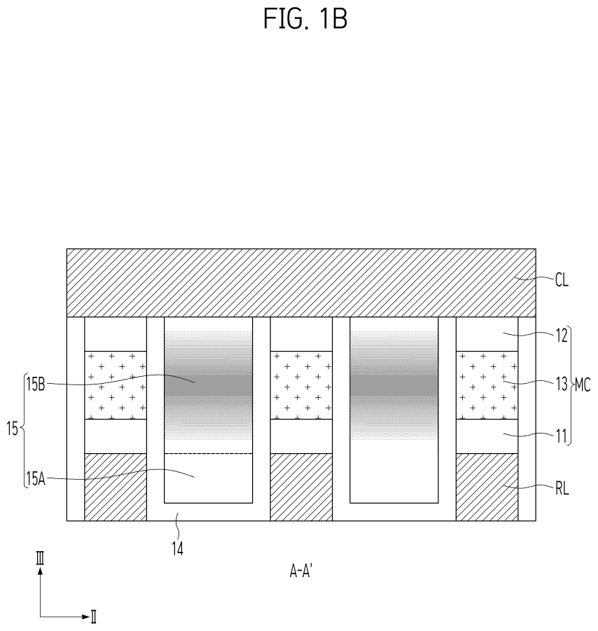

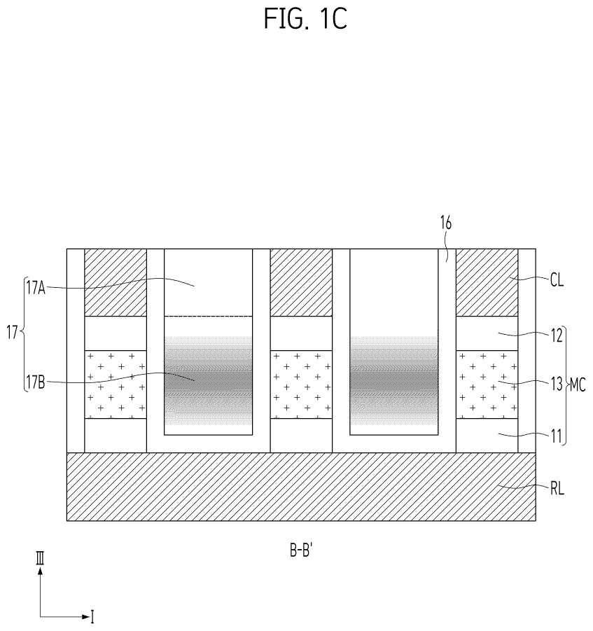

FIGS. 1A to 1C are diagrams illustrating the structure of a semiconductor device in accordance with an embodiment. FIG. 1A is a plan view, FIG. 1B is a cross-sectional view taken along line A-A′ of FIG. 1A, and FIG. 1C is a cross-sectional view taken along line B-B′ of FIG. 1A.

Referring to FIGS. 1A to 1C, the semiconductor device may include a row line RL, a column line CL, and a memory cell MC. The semiconductor device may further include at least one of a first capping layer 14, a second capping layer 16, a first gap-fill insulating layer 15, and a second gap-fill insulating layer 17.

The row line RL may extend in a first direction I, and the column line CL may extend in a second direction II intersecting the first direction I. The row line RL and the column line CL may be stacked along a third direction III. The third direction III may be a direction perpendicular to a plane defined by the first direction I and the second direction II. The row line RL may be a word line and the column line CL may be a bit line or the row line RL may be a bit line and the column line CL may be a word line.

The memory cell MC may be connected between the row line RL and the column line CL. The memory cell MC may be a resistive memory cell including a variable resistance layer 13. Each of the memory cells MC may include a select element and/or a memory element. As an example, each of the memory cells MC may include a first electrode 11, a second electrode 12, and a variable resistance layer 13, and the variable resistance layer 13 may be located between the first electrode 11 and the second electrode 12.

The variable resistance layer 13 may have characteristics that it reversibly transitions between different resistance states depending on a voltage or a current applied to the memory cell MC. As an example, when the variable resistance layer 13 has a low resistance state, data ‘1’ may be stored, and when the variable resistance layer 13 has a high resistance state, data ‘0’ may be stored.

As an example, the variable resistance layer 13 may include a resistive material. An electrical path is generated or disappears in the variable resistance layer 13, such that data may be stored. As an example, the variable resistance layer 13 may include transition metal oxide or include metal oxide such as a perovskite-based material.

As an example, the variable resistance layer 13 may have a magnetic tunnel junction (MTJ) structure including a magnetization pinned layer, a tunnel barrier layer, and a magnetization free layer. The data may be stored according to a change in magnetization direction of the magnetization free layer with respect to a magnetization direction of the magnetization pinned layer. As an example, the magnetization pinned layer and the magnetization free layer may each include a magnetic material, and the tunnel barrier layer may include metal oxide.

As an example, the variable resistance layer 13 may include a phase change material or include a chalcogenide-based material. The variable resistance layer 13 may change its phase according to a program operation. As an example, the variable resistance layer 13 may have a low resistance crystalline state through a set operation. As an example, the variable resistance layer 13 may have a high resistance amorphous state through a reset operation. Accordingly, the data may be stored in the memory cell using a resistance difference depending on a phase of the variable resistance layer 13.

As an example, the variable resistance layer 13 may include a variable resistance material whose resistance changes without a phase change or include a chalcogenide-based material. The variable resistance layer 13 may maintain its phase after the program operation. As an example, the variable resistance layer 13 may have an amorphous state, and may maintain the amorphous state without changing to a crystalline state after the program operation. A threshold voltage of the memory cell may be changed depending on a program voltage applied to the memory cell, and the memory cell may be programmed to at least two states. As an example, the memory cell may be programmed to a set state or a reset state using program voltages having different polarities. Accordingly, the data may be stored in the memory cell using a difference in the threshold voltage of the memory cell.

The first electrode 11 may be electrically connected to the row line RL, and the second electrode 12 may be electrically connected to the column line CL. The first electrode 11 and the second electrode 12 may each include polysilicon, tungsten (W), tungsten nitride (WNₓ), tungsten silicide (WSiₓ), titanium (Ti), titanium nitride (TiNₓ), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbonitride (SiCN), aluminum (Al), copper (Cu), zinc (Zn), nickel (Ni), cobalt (Co), lead (Pb), platinum (Pt), molybdenum (Mo), ruthenium (Ru), or the like, or include combinations thereof. As an example, at least one of the first electrode 11 and the second electrode 12 may each include metal nitride. The row line RL and the column line CL may each include metal such as tungsten (W) or molybdenum (Mo).

The first gap-fill insulating layer 15 may cover a sidewall of the memory cell MC. The first gap-fill insulating layers 15 may be located between the memory cells MC adjacent to each other in the second direction II, and may extend between the row lines RL. The first capping layers 14 may be located on sidewalls of the memory cells MC adjacent to each other in the second direction II. The first capping layers 14 may be located between the first gap-fill insulating layers 15 and the memory cells MC and between the first gap-fill insulating layers 15 and the row lines RL.

The first gap-fill insulating layer 15 may include a first portion 15A located between the row lines RL and a second portion 15B located between the memory cells MC adjacent to each other in the second direction II. For example, the first gap-fill insulating layer 15 may include a first portion 15A located between an adjacent pair of the row lines RL in the second direction II and a second portion 15B located between an adjacent pair of the memory cells MC in the second direction II. As an example, the second portion 15B may be located between the variable resistance layers 13.

The first portion 15A and the second portion 15B may have different nitrogen concentrations. The first portion 15A may have a first nitrogen concentration, and the second portion 15B may have a second nitrogen concentration higher than the first nitrogen concentration. Here, the first nitrogen concentration may be an average value, a maximum value, or a minimum value in the nitrogen concentration of the first portion 15A. The second nitrogen concentration may be an average value, a maximum value, or a minimum value in the nitrogen concentration of the second portion 15B. In some embodiments, the first gap-fill insulating layer 15 may have a nitrogen concentration gradient. The first gap-fill insulating layer 15 may have a given (e.g., predetermined) nitrogen concentration profile. For example, the nitrogen concentration profile may have a peak value at levels of the second portions 15B corresponding to the variable resistance layers 13. Specifically, the nitrogen concentration profile of the first gap-fill insulating layer 15 may have a peak value between upper and lower surfaces of the variable resistance layer 13. In some embodiments, the nitrogen concentration profile of the first gap-fill insulating layer 15 may have a peak value at a location of the memory cell MC where a thermal stress generated in the memory cell MC reaches a maximum value, thereby effectively suppressing a thermal deformation associated with the thermal stress. For example, the nitrogen concentration profile of the first gap-fill insulating layer 15 may have a peak value at either a first interface between the variable resistance layer 13 and the second electrode 12 or a second interface between the variable resistance layer 13 and the first electrode 11. Alternatively, the nitrogen concentration gradient of the first gap-fill insulating layer 15 may have a peak value at a middle of the variable resistance layer 13.

The second portion 15B may be a portion doped with nitrogen by nitrogen plasma treatment. As an example, the first portion 15A may include silicon oxide (e.g., SiO₂), and may be nitrogen-free or include a trace amount of nitrogen. In other words, the first portion 15A may be substantially nitrogen-free. The second portion 15B may include silicon oxynitride (e.g., SiON) and/or silicon nitride (SiNₓ).

The first portion 15A may include a low-k material having a lower dielectric constant than the second portion 15B. Accordingly, a spike current may be reduced compared to when the first gap-fill insulating layer 15 is entirely formed of a material having a relatively higher dielectric constant than the low-k material. Also, the first portion 15A has a relatively low thermal conductivity, and thus heat transfer from the memory cell MC may be limited to facilitate thermal-induced switching of the memory cell MC. In addition, the second portion 15B may have a higher mechanical strength than the first portion 15A, and may include a material a higher Young's modulus than the first portion 15A. When the set/reset operation of the memory cell MC is repeatedly performed, the variable resistance layer 13 may shrink and/or expand, and deformation of the variable resistance layer 13 may increase due to thermal stress. In such a case, a void may be formed inside the memory cell MC, and reliability of the memory cell MC may be decreased. Accordingly, by including the second portion 15B whose mechanical strength is increased in the first gap-fill insulating layer 15, the shrinkage, the expansion, and/or the deformation of the variable resistance layer 13 may be reduced. For example, since deformation of the memory cell MC may be reduced, growing or merging small voids into large voids in the memory cell MC may be effectively suppressed. As a result, reliability of the memory cell MC may be significantly improved compared to when the first gap-fill insulating layer 15 does not include the second portion 15B.

The second gap-fill insulating layer 17 may cover a sidewall of the memory cell MC. The second gap-fill insulating layers 17 may be located between the memory cells MC adjacent to each other in the first direction I, and may extend between the column lines CL. The second capping layers 16 may be located on sidewalls of the memory cells MC adjacent to each other in the first direction I. The second capping layers 16 may be located between the second gap-fill insulating layers 17 and the memory cells MC and between the second gap-fill insulating layers 17 and the column lines CL. The first and second capping layers 14 and 16 may each include silicon nitride.

The second gap-fill insulating layer 17 may include a third portion 17A located between the column lines CL and a fourth portion 17B located between the memory cells MC. For example, the second gap-fill insulating layer 17 may include a third portion 17A located between an adjacent pair of the column lines CL in the first direction I and a fourth portion 17B located between an adjacent pair of the memory cells MC in the first direction I. As an example, the fourth portion 17B may be located between the variable resistance layers 13. The third portion 17A may have a third nitrogen concentration, and the fourth portion 17B may have a fourth nitrogen concentration higher than the third nitrogen concentration. The fourth portion 17B may be a portion doped with nitrogen by nitrogen plasma treatment. As an example, the third portion 17A may include silicon oxide (e.g., SiO₂), and may be nitrogen-free or may include a trace amount of nitrogen. In other words, the third portion 17A may be substantially nitrogen-free. The fourth portion 17B may include silicon oxynitride (e.g., SiON) and/or silicon nitride (SiNₓ).

The third portion 17A may include a material having a lower dielectric constant than the fourth portion 17B. Accordingly, a spike current may be reduced compared to when the second gap-fill insulating layer 17 is entirely formed of a material having a relatively higher dielectric constant than the low-k material. Also, the first portion 15A has a relatively low thermal conductivity, and thus heat transfer from the memory cell MC may be limited to facilitate thermal-induced switching of the memory cell MC. In addition, the fourth portion 17B may have a higher mechanical strength than the third portion 17A, and may include a material a higher Young's modulus than the third portion 17A. Accordingly, since deformation of the memory cell MC may be reduced, growing or merging small voids into large voids in the memory cell MC may be effectively suppressed. As a result, reliability of the memory cell MC may be significantly improved compared to when the second gap-fill insulating layer 17 does not include the fourth portion 17B.

According to the structure described above, the first gap-fill insulating layer 15 may include the first portion 15A and the second portion 15B having different characteristics. The spike current may be reduced through the first portion 15A, and the mechanical strength of the first gap-fill insulating layer 15 may be increased through the second portion 15B. By increasing mechanical strength of a portion of the first gap-fill insulating layer 15 covering the memory cell MC, it is possible to reduce the deformation of the memory cell MC. By increasing mechanical strength of a portion of the first gap-fill insulating layer 15 covering the variable resistance layer 13, it is possible to reduce the shrinkage and/or the expansion of the variable resistance layer 13.

Similar to the first gap-fill insulating layer 15, the second gap-fill insulating layer 17 may also include the third portion 17A and the fourth portion 17B having different characteristics. The spike current may be reduced through the third portion 17A, and mechanical strength of the second gap-fill insulating layer 17 may be increased through the fourth portion 17B. By partially increasing the mechanical strength of the first and second gap-fill insulating layers 15 and 17 together surrounding the sidewalls of the memory cells MC, it is possible to reduce the deformation of the memory cells MC. For reference, it is also possible for only one of the first gap-fill insulating layer 15 and the second gap-fill insulating layer 17 to have a nitrogen concentration profile.

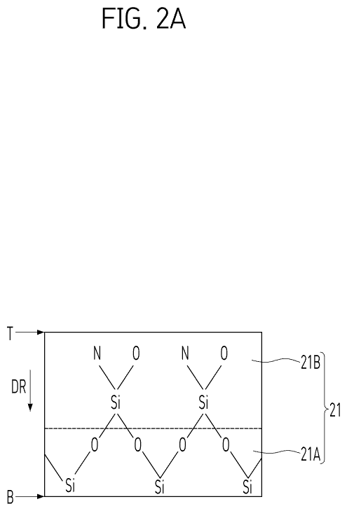

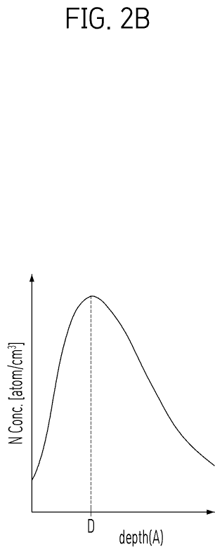

FIGS. 2A and 2B are diagrams illustrating characteristics of a semiconductor device in accordance with an embodiment. Hereinafter, the content overlapping with the previously described content may be omitted.

Referring to FIGS. 2A and 2B, a gap-fill insulating layer 21 may have a nitrogen concentration profile in which a nitrogen concentration changes in a depth direction DR from a top T toward a bottom B. A portion of the gap-fill insulating layer 21 may have a higher nitrogen concentration than the remaining portion of the gap-fill insulating layer 21, and may have a higher mechanical strength than the remaining portion of the gap-fill insulating layer 21.

Referring to FIG. 2A, the gap-fill insulating layer 21 may include a first portion 21A and a second portion 21B having a higher nitrogen concentration than the first portion 21A. As an example, the first portion 21A may include silicon oxide, and the second portion 21B may include silicon oxynitride and/or silicon nitride. The second portion 21B may be a portion where oxygen of a silicon oxide layer is at least partially replaced with nitrogen by nitrogen plasma treatment.

FIG. 2B is a graph illustrating a change in nitrogen concentration (or a nitrogen concentration profile) depending on a depth of the gap-fill insulating layer 21. An x-axis of the graph represents a depth, and a y-axis of the graph represents a nitrogen concentration. Referring to the graph, as a depth increases from the top T of the gap-fill insulating layer 21 to a depth D, the nitrogen concentration may increase. As a depth further increases from the depth D to the bottom B of the gap-fill insulating layer 21, the nitrogen concentration may decrease. In other words, the gap-fill insulating layer 21 may have a nitrogen concentration profile that increases from a top of the gap-fill insulating layer 21 to a first level (e.g., corresponding to the depth D) and that decreases from the first level to a bottom of the gap-fill insulating layer 21. The first level may correspond to a variable resistance layer (e.g., a level higher than a bottom of the variable resistance layer and lower than a top of the variable resistance layer) adjacent to the gap-fill insulating layer 21.

The nitrogen concentration may be the highest (or a peak value) at the depth D of the gap-fill insulating layer 21. The depth D may be a level corresponding to the memory cell MC, and may be a level corresponding to a variable resistance layer. As an example, the gap-fill insulating layer 21 may correspond to the first gap-fill insulating layer 15 and/or the second gap-fill insulating layer 17 of the embodiment described above with reference to FIGS. 1A to 1C. The depth D may be a level higher than a bottom of the variable resistance layer 13 and lower than a top of the variable resistance layer 13. In some embodiments, the depth D may be a level corresponding to an interface between the variable resistance layer 13 and an electrode (e.g., the first electrode 12 or the first electrode 11). Alternatively, the depth D may be a level corresponding to a middle of the variable resistance layer 13.

According to the structure described above, the gap-fill insulating layer 21 may have a nitrogen concentration profile, and the nitrogen concentration of the gap-fill insulating layer 21 may be the highest at the level corresponding to the variable resistance layer 13. Accordingly, deformation of the memory cell MC due to shrinkage and/or expansion of the variable resistance layer 13 may be reduced to improve reliability of the memory cell MC.

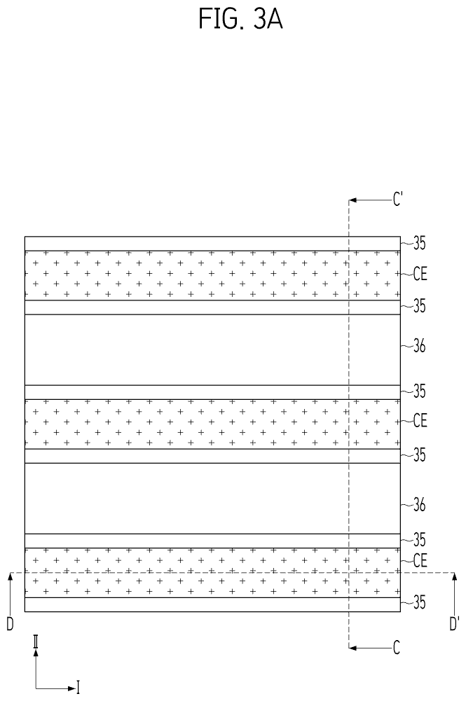

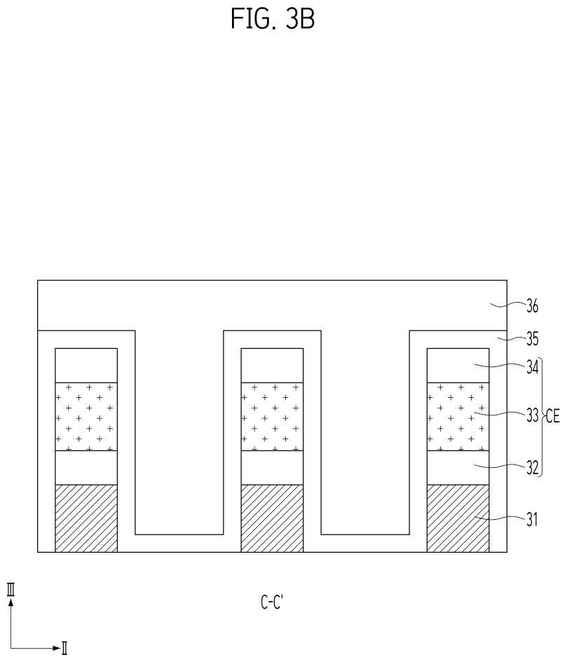

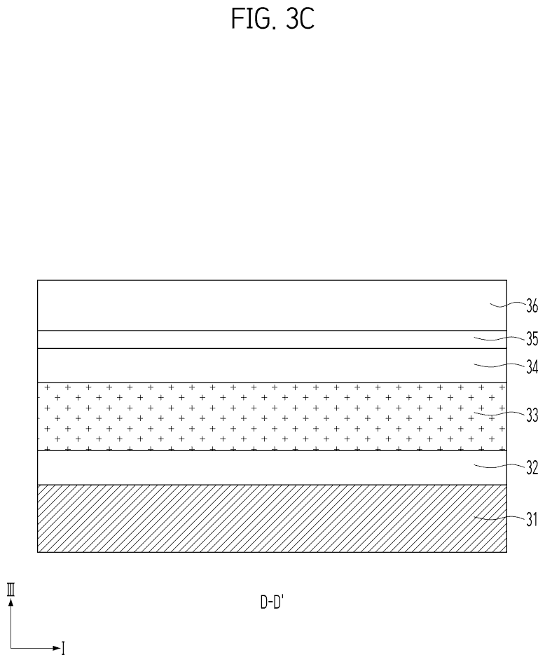

FIGS. 3A, 4A, 5A, and 6A, FIGS. 3B, 4B, 5B, and 6B, and FIGS. 3C, 4C, 5C, and 6C are diagrams for describing a method of manufacturing a semiconductor device in accordance with an embodiment. FIGS. 3A, 4A, 5A, and 6A are plan views, FIGS. 3B, 4B, 5B, and 6B are cross-sectional views taken along lines C-C′ of FIGS. 3A, 4A, 5A, and 6A, respectively, and FIGS. 3C, 4C, 5C, and 6C are cross-sectional views taken along lines D-D′ of FIGS. 3A, 4A, 5A, and 6A, respectively. Hereinafter, some contents overlapping with the previously described contents may be omitted for the interest of brevity.

Referring to FIGS. 3A to 3C, row lines 31 and cell lines CE extending in the first direction I are formed. The cell line CE may include a first electrode (or a first electrode layer) 32, a variable resistance layer 33, and a second electrode (or a second electrode layer) 34. The first electrode 32 and/or the second electrode 34 may each include metal nitride.

Subsequently, a first capping layer 35 may be formed on sidewalls of the cell lines CE and the row lines 31. The first capping layer 35 may include silicon nitride. Subsequently, a first flowable oxide layer 36 may be formed on the cell lines CE or on the first capping layer 35. As an example, the first flowable oxide layer 36 may include polysilazane (PSZ), hydrogen silsesquioxane (HSQ), borophosphosilicate glass (BPSG), spin on dielectric (SOD), colloidal solution (SOL), or the like. The first flowable oxide layer 36 may fill empty spaces between the cell lines CE.

Subsequently, the first flowable oxide layer 36 may be heat-treated at a first temperature. The first temperature may be determined in a range to substantially prevent damage to the variable resistance layer 33 and to sufficiently harden the first flowable oxide layer 36. As an example, the first temperature may be about 200° C. to about 300° C. Through this, the first flowable oxide layer 36 may be hardened.

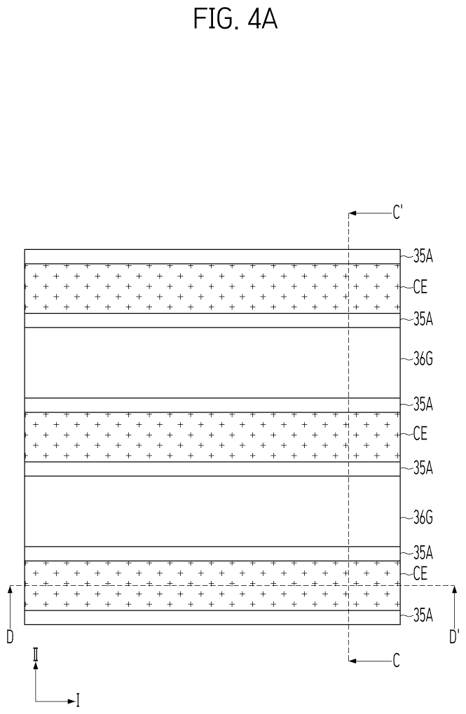

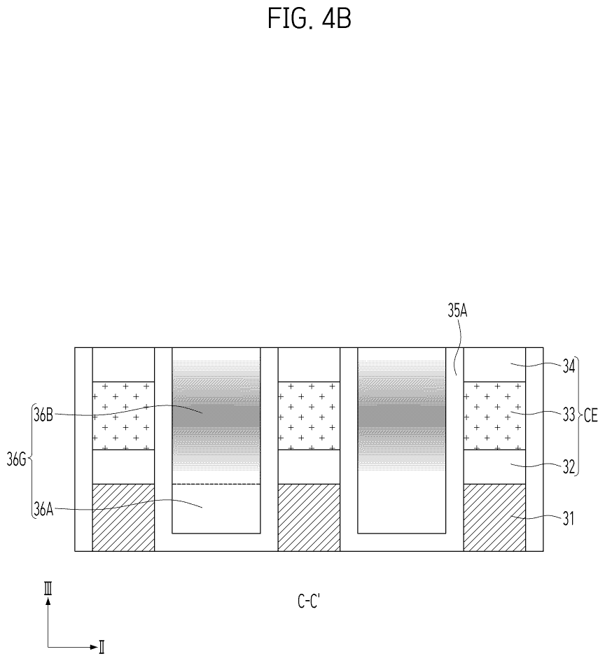

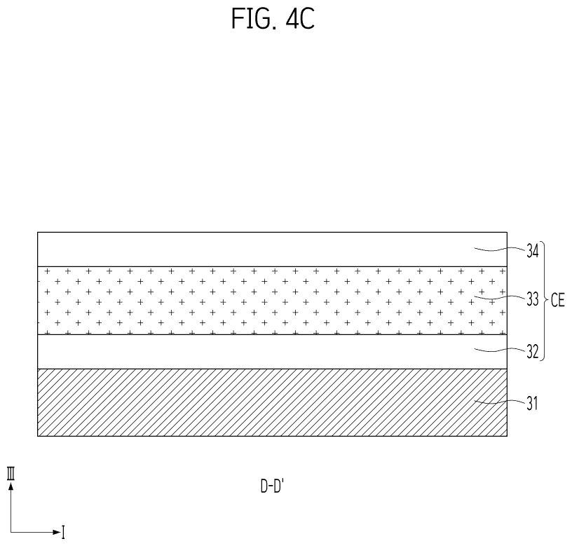

Referring to FIGS. 4A to 4C, first gap-fill insulating layers 36G may be formed between the cell lines CE by planarizing the heat-treated first flowable oxide layer 36. Each of the first gap-fill insulating layers 36G may extend in the first direction I, and may include a first portion 36A and a second portion 36B. The first portion 36A may be located between the row lines 31 (e.g., an adjacent pair of the row lines 31 in the second direction II), and the second portion 36B may be located between the cell lines CE (e.g., an adjacent pair of the cell lines CE in the second direction II). The first gap-fill insulating layers 36G may each include silicon oxide. When the first flowable oxide layer 36 is planarized, a portion of the first capping layer 35 may also be etched. The remaining portion of the first capping layer 35 may be referred to as first capping layers (or first capping patterns) 35A.

Subsequently, the first gap-fill insulating layers 36G may be plasma-nitrided. As an example, nitrogen plasma treatment (e.g., a plasma nitridation process) may be performed in a continuous wave manner and/or a pulsed wave manner. The plasma nitridation process may be performed at a second temperature. The second temperature may be determined in a range to substantially prevent damage to the variable resistance layer 33. As an example, the second temperature may be about 25° C. to about 300° C. The second temperature may be lower than the first temperature, and may be a relatively low temperature. The first temperature may be about 200° C. (e.g., 195° C.-204° C.) to about 300° C. (e.g., 295° C.-304° C.), and the second temperature may be about 25° C. (e.g., 24.5° C. to 25.4° C.) to about 150° C. (e.g., 145° C.-154° C.).

When the first gap-fill insulating layers 36G are plasma-nitrided, efficiency and characteristics of a nitridation reaction may be changed depending on a process temperature. When the second temperature is lower than 25° C., activation energy required for the nitridation reaction is insufficient, and thus, nitrogen substitution might not occur. When the second temperature is higher than 150° C., nitrogen substitution might not be sufficiently concentrated on a target depth and may occur over a wide range. When the second temperature is higher than 300° C., the variable resistance layer 33 may be significantly damaged. Accordingly, by limiting the second temperature to 25° C. to 300° C. or 25 to 150° C., it is possible to nitride the first gap-fill insulating layer 36G while substantially preventing damage to the variable resistance layer 33 and sufficiently concentrating nitrogen substitution on the target depth to effectively reduce thermal deformation of the variable resistance layer 33. As a result, reliability of the memory cell MC may be significantly improved.

The target depth of the plasma nitridation process may be located in the second portion 36B. As an example, the target depth may be a level corresponding to the variable resistance layer 33, and may be between a bottom of the variable resistance layer 33 and a top of the variable resistance layer 33. In some embodiments, the target depth may be a level corresponding to an interface between the variable resistance layer 33 and an electrode layer (e.g., the first electrode layer 32 or the second electrode layer 34). Alternatively, the target depth may be a level corresponding to a middle of the variable resistance layer 33. Through this, the first gap-fill insulating layer 36G has a nitrogen concentration profile. In some embodiments, the first gap-fill insulating layer 36G may have a nitrogen concentration profile across the first portion 36A and the second portion 36B. In some embodiments, the first portion 36A may be nitrogen-free or may include a trace amount of nitrogen.

When the plasma nitridation process is performed, the second electrode 34 and/or the first capping layers 35A may be nitrided. As an example, the second electrode 34 may include metal nitride and the first capping layers 35A may include silicon nitride. As a result, even though the second electrode 34 and/or the first capping layers 35A are nitrided during the plasma nitridation process, physical properties and functions of the second electrode 34 and the first capping layers 35A may be substantially maintained.

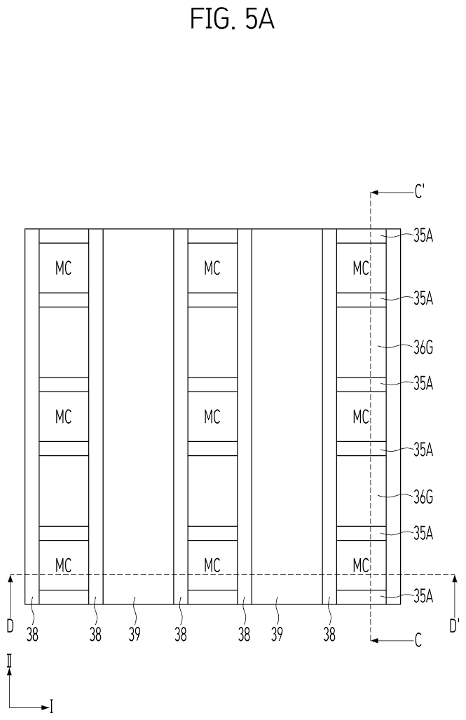

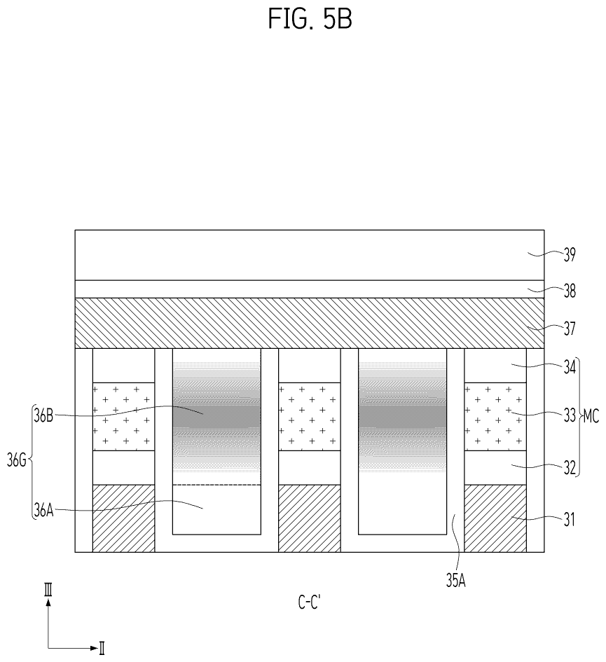

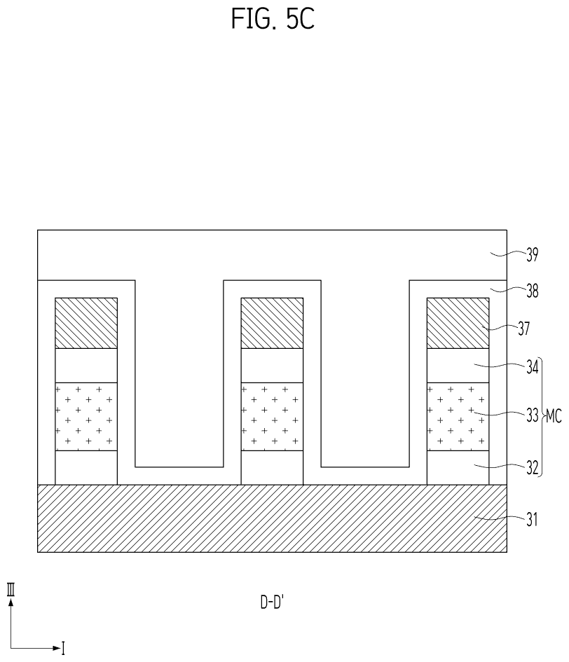

Referring to FIGS. 5A to 5C, column lines 37 extending in the second direction II may be formed on the cell lines CE. Subsequently, memory cells MC arranged in the first direction I and the second direction II may be formed by etching the cell lines CE. Subsequently, a second capping layer 38 may be formed on sidewalls of the memory cells MC and the column lines 37. The second capping layer 38 may include silicon nitride.

Subsequently, a second flowable oxide layer 39 may be formed on the memory cells MC or on the second capping layer 38. As an example, the second flowable oxide layer 39 may include polysilazane (PSZ), hydrogen silsesquioxane (HSQ), borophosphosilicate glass (BPSG), spin on dielectric (SOD), colloidal solution (SOL), or the like. The second flowable oxide layer 39 may fill empty spaces between the memory cells MC and between the column lines 37.

Subsequently, the second flowable oxide layer 39 may be heat-treated at a first temperature. The first temperature may be determined in a range to substantially prevent damage to the variable resistance layer 33. As an example, the first temperature may be about 200° C. to about 300° C.

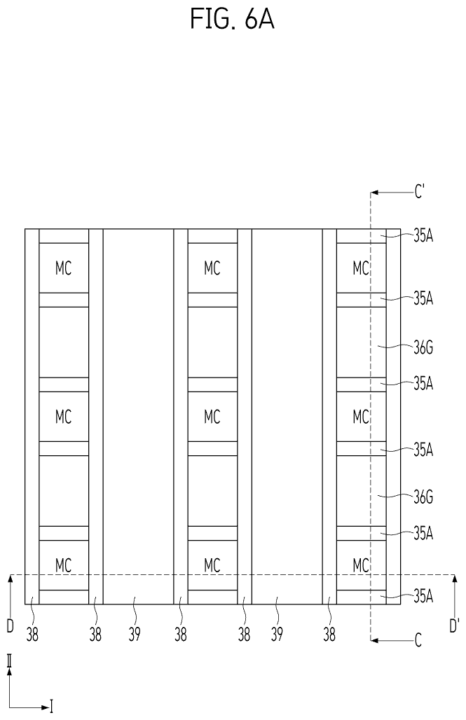

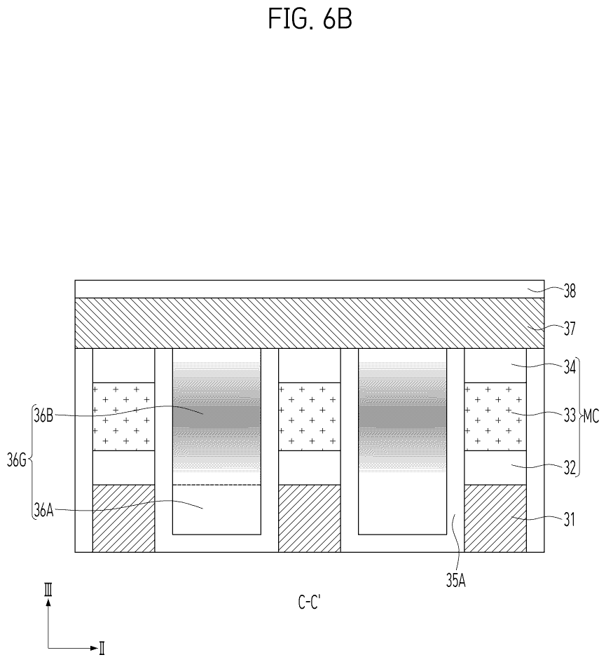

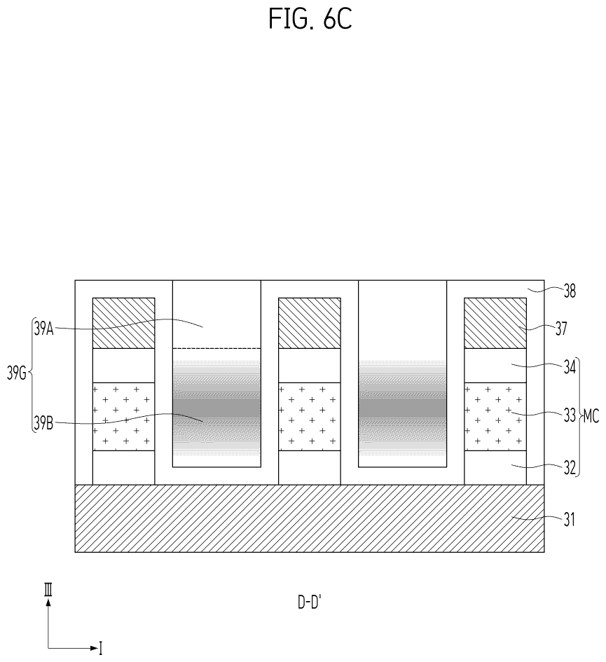

Referring to FIGS. 6A to 6C, second gap-fill insulating layers 39G may be formed between the memory cells MC and between the column lines 37 adjacent to each other in the first direction I by planarizing the heat-treated second flowable oxide layer 39. For example, each of the second gap-fill insulating layers 39G may be formed between an adjacent pair of the memory cells MC in the first direction I, and between an adjacent pair of the column lines 37 in the first direction I. Each of the second gap-fill insulating layers 39G may extend in the second direction II, and may include a third portion 39A and a fourth portion 39B. The third portion 39A may be located between the column lines 37, and the fourth portion 39B may be located between the memory cells MC. The second gap-fill insulating layers 39G may each include silicon oxide.

Subsequently, the second gap-fill insulating layers 39G may be plasma-nitrided. As an example, nitrogen plasma treatment (e.g., a plasma nitridation process) may be performed in a continuous wave manner and/or a pulsed wave manner. The plasma nitridation process may be performed at a second temperature. The second temperature may be determined in a range to substantially prevent damage to the variable resistance layer 33. As an example, the second temperature may be about 25° C. to about 300° C. The second temperature may be lower than the first temperature, and may be a relatively low temperature. The first temperature may be about 200° C. to about 300° C., and the second temperature may be about 25° C. to about 150° C.

A target depth of the plasma nitridation process may be located in the fourth portion 39B. As an example, the target depth may be a level corresponding to the variable resistance layer 33, and may be between a bottom of the variable resistance layer 33 and a top of the variable resistance layer 33. Through this, the second gap-fill insulating layer 39G has a nitrogen concentration profile. In some embodiments, the second gap-fill insulating layer 39G may have a nitrogen concentration profile across the third portion 39A and the fourth portion 39B. In some embodiments, the third portion 39A may be nitrogen-free or may include a trace amount of nitrogen.

When the plasma nitridation process is performed, the second capping layer 38 may be nitrided. As an example, the second capping layer 38 may silicon nitride. As a result, even though the second capping layer 38 is nitrided during the plasma nitridation process, physical properties and a function of the second capping layer 38 may be sufficiently maintained.

According to the method described above, plasma-nitriding a portion of the first gap-fill insulating layer 36G, it is possible to increase mechanical strength of the first gap-fill insulating layer 36G. If the first gap-fill insulating layer 36G were entirely plasma-nitrided, gap-fill characteristics of the first gap-fill insulating layer 36G may be deteriorated or parasitic capacitance of the first gap-fill insulating layer 36G may be increased. Accordingly, by plasma-nitriding a portion (e.g., the second portion 36B) of the first gap-fill insulating layer 36G, it is possible to improve the mechanical strength of the first gap-fill insulating layer 36G and characteristics of the first gap-fill insulating layer 36G as a diffusion barrier through the second portion 36B, while sufficiently maintaining the gap-fill characteristics and the parasitic capacitance of the first gap-fill insulating layer 36G through the first portion 36A. The improved mechanical strength through the second portion 36B may reduce deformation of the memory cell MC, and the improved diffusion barrier characteristics through the second portion 36B may reduce damage to the memory cell MC due to chemicals such as oxygen (O), fluorine (F), and chlorine (CI) in a manufacturing process.

Similar to the first gap-fill insulating layer 36G, by plasma-nitriding a portion of the second gap-fill insulating layer 39G, it is possible to increase mechanical strength of the second gap-fill insulating layer 39G. For reference, it is also possible to plasma-nitride only one of the first gap-fill insulating layer 36G and the second gap-fill insulating layer 39G.

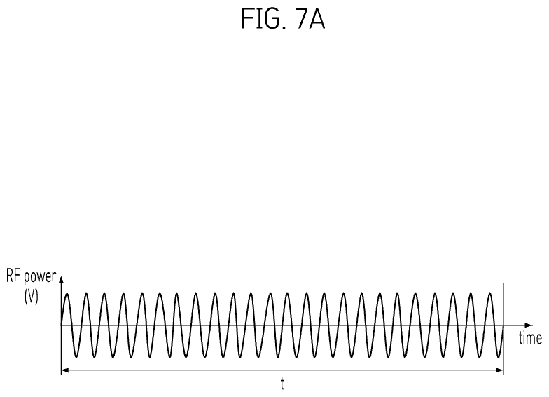

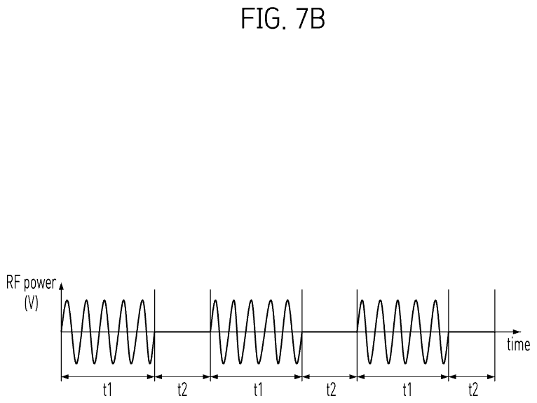

FIGS. 7A and 7B are diagrams for describing a method of manufacturing a semiconductor device in accordance with an embodiment. Graphs of FIGS. 7A and 7B illustrate radio frequency (RF) power of a plasma device. An x-axis of each graph represents a time, and a y-axis of each graph represents RF power.

When the plasma device plasma-nitrides a gap-fill insulating layer, the plasma device may supply RF power in a continuous wave (CW) manner or a pulsed-wave (PW) manner. FIG. 7A illustrates a CW manner in which RF power is supplied without pulse modulation. According to the CW manner, an electron density and an electron temperature may be kept substantially constant when plasma is generated. FIG. 7B illustrates a PW manner in which RF power is supplied with pulse modulation. According to the PW manner, an electron density and an electron temperature may be periodically changed when plasma is generated.

When the RF power is supplied, a plasma treatment gas is decomposed, such that ions and/or radicals are generated. In this case, energy distributions of the ions and/or the radicals may be changed by adjusting a duty cycle. The duty cycle refers to a ratio of a supply time of the RF power in a single cycle, and may be calculated through Equation 1. t1 refers to an on-time during which the RF power is supplied, and t2 refers to an off-time during which the RF power is not supplied. The duty cycle may be expressed as a ratio of the on-time to the sum of the on-time and the off-time.

$$Duty Cycle ( \% ) = \frac{t 1}{t 1 + t 2} \qquad [ Equation 1 ]$$

When a plasma nitridation process is performed in the PW manner, a doping dispersion of nitrogen may be smaller than that when the plasma nitridation process is performed in the CW manner. In a case of the PW manner, a target depth of the plasma nitridation process may be adjusted according to the duty cycle. As an example, the target depth may be reduced by reducing the duty cycle, and nitrogen may be doped close to a surface. In addition, according to the PW manner, mobility of the radicals is relatively slowly reduced compared to the ions during the off-time. In such a case, the radicals may move to an inner portion of the gap-fill insulating layer to generate a chemical reaction, and nitrogen may be doped to concentrate on the target depth. Accordingly, by supplying the RF power in the PW manner, it is possible to selectively dope nitrogen at a level corresponding to a variable resistance layer and selectively harden the gap-fill insulating layer around the variable resistance layer.

Although some embodiments of the present disclosure have been described above with reference to the accompanying drawings, various embodiments of the present disclosure are not limited to the above-described embodiments. Various types of substitutions, modifications, changes, and combinations for the embodiments may be made by those skilled in the art, to which the present disclosure pertains, and these substitutions, modifications, changes, and combinations belong to the scope of embodiments of the present disclosure.

What is claimed is:

1. A semiconductor device comprising:
row lines extending along a first direction;
column lines extending along a second direction that intersects the first direction;
memory cells located between the row lines and the column lines and including variable resistance layers; and
a first gap-fill insulating layer including a first portion located between an adjacent pair of the row lines in the second direction and a second portion located between an adjacent pair of the memory cells in the second direction, the first portion having a first nitrogen concentration, and the second portion having a second nitrogen concentration higher than the first nitrogen concentration.

2. The semiconductor device of claim 1, wherein the first gap-fill insulating layer has a nitrogen concentration profile.

3. The semiconductor device of claim 2, wherein the nitrogen concentration profile of the first gap-fill insulating layer has a peak value at levels corresponding to the variable resistance layers.

4. The semiconductor device of claim 1, wherein the second portion has a higher Young's modulus than the first portion.

5. The semiconductor device of claim 1, wherein the first portion includes a material having a lower dielectric constant than the second portion.

6. The semiconductor device of claim 1, wherein each of the memory cells comprises:
a first electrode;
a second electrode; and
a corresponding one of the variable resistance layers located between the first electrode and the second electrode.

7. The semiconductor device of claim 6, wherein at least one of the first electrode or the second electrode includes metal nitride.

8. The semiconductor device of claim 6, wherein each of the variable resistance layers maintains an amorphous state after a program operation.

9. The semiconductor device of claim 1, further comprising a first capping layer located between the first gap-fill insulating layer and the memory cells and between the first gap-fill insulating layer and the row lines.

10. The semiconductor device of claim 9, wherein the first capping layer includes silicon nitride.

11. The semiconductor device of claim 1, further comprising a second gap-fill insulating layer including a third portion located between an adjacent pair of the column lines in the first direction and a fourth portion located between an adjacent pair of the memory cells adjacent in the first direction, the third portion having a third nitrogen concentration, and the fourth portion having a fourth nitrogen concentration higher than the third nitrogen concentration.

12. A semiconductor device comprising:
a row line extending along a first direction;
a column line extending along a second direction that intersects the first direction;
a memory cell located between the row line and the column line and including a variable resistance layer; and
a gap-fill insulating layer covering a sidewall of the memory cell, and having a nitrogen concentration profile, the nitrogen concentration profile increasing from a top of the gap-fill insulating layer to a first level corresponding to the variable resistance layer and decreasing from the first level to a bottom of the gap-fill insulating layer.

13. The semiconductor device of claim 12, wherein the memory cell comprises:
a first electrode;
the variable resistance layer located on the first electrode; and
a second electrode located on the variable resistance layer.

14. The semiconductor device of claim 13, wherein the first level is higher than a bottom of the variable resistance layer and lower than a top of the variable resistance layer.

15. A method of manufacturing a semiconductor device, the method comprising:
forming cell lines that extend along a first direction and include variable resistance layers;
forming a first flowable oxide layer on the cell lines;
heat-treating the first flowable oxide layer;
forming a first gap-fill insulating layer between the cell lines by planarizing the heat-treated first flowable oxide layer; and
performing first nitrogen plasma treatment on the first gap-fill insulating layer.

16. The method of claim 15, wherein the first nitrogen plasma treatment is performed in a pulsed-wave (PW) manner.

17. The method of claim 15, wherein the heat-treating is performed at a first temperature, and the first nitrogen plasma treatment is performed at a second temperature lower than the first temperature.

18. The method of claim 17, wherein the first temperature is about 200° C. to about 300° C., and the second temperature is about 25° C. to about 150° C.

19. The method of claim 15, wherein a target depth of the first nitrogen plasma treatment is between a bottom of each of the variable resistance layers and a top of each of the variable resistance layers.

20. The method of claim 15, further comprising:
forming memory cells by etching the cell lines, the memory cells being arranged in the first direction and a second direction that intersects the first direction;
forming a second gap-fill insulating layer between an adjacent pair of the memory cells in the first direction; and
performing second nitrogen plasma treatment on the second gap-fill insulating layer.

21. The method of claim 20, wherein the forming of the second gap-fill insulating layer comprises:
forming a second flowable oxide layer on the memory cells;
heat-treating the second flowable oxide layer; and
forming the second gap-fill insulating layer by planarizing the heat-treated second flowable oxide layer.

22. A method of manufacturing a semiconductor device, the method comprising:
forming cell lines that extend along a first direction and include variable resistance layers;
forming a first gap-fill insulating layer between the cell lines;
forming memory cells by etching the cell lines and the first gap-fill insulating layer, the memory cells being arranged in the first direction and a second direction intersecting the first direction;
forming a flowable oxide layer on the memory cells;
heat-treating the flowable oxide layer;
forming a second gap-fill insulating layer between the memory cells by planarizing the heat-treated flowable oxide layer; and
performing nitrogen plasma treatment on the second gap-fill insulating layer.

23. The method of claim 22, wherein the nitrogen plasma treatment is performed in a pulsed-wave (PW) manner.

24. The method of claim 22, wherein the heat-treating is performed at a first temperature, and the nitrogen plasma treatment is performed at a second temperature lower than the first temperature.

25. The method of claim 24, wherein the first temperature is about 200° C. to about 300° C., and the second temperature is about 25° C. to about 150° C.

26. The method of claim 22, wherein a target depth of the nitrogen plasma treatment is between a bottom of each of the variable resistance layers and a top of each of the variable resistance layers.
